(19) United States
(12) Patent Application Publication
(10) Pub. No.: US 2016/0270247 A1
(43) Pub. Date: Sep. 15, 2016

(54) LAMINATING SAPPHIRE AND GLASS USING INTERMOLECULAR FORCE ADHESION

(71) Applicant: Apple Inc., Cupertino, CA (US)

(72) Inventors: Christopher D. Jones, Cupertino, CA (US); Dale N. Memering, Cupertino, CA (US)

(21) Appl. No.: 15/059,216

(22) Filed: Mar. 2, 2016

Related U.S. Application Data
(60) Provisional application No. 62/131,602, filed on Mar. 11, 2015.

(51) Int. Cl. H05K 5/03; H05K 5/00

(52) U.S. Cl. CPC H05K 5/03; H05K 5/0017

(57) ABSTRACT

An electronic device comprises a housing, a display coupled to the housing, and a protective cover coupled to the housing and covering the display. The protective cover comprises a transparent layer having a first surface facing the display and a second surface opposite the first surface. The protective cover also comprises a sapphire layer having a third surface corresponding to an exterior surface of the electronic device. The sapphire layer also has a fourth surface opposite the third surface and bonded to the second surface of the transparent layer via intermolecular forces.

### CROSS-REFERENCE TO RELATED APPLICATION

This application is a nonprovisional patent application of U.S. Provisional Patent Application No. 62/131,602, filed Mar. 11, 2015 and titled “Laminating Sapphire and Glass Using Intermolecular Force Adhesion,” the disclosure of which is hereby incorporated herein by reference in its entirety.

### FIELD

The subject matter of this disclosure relates generally to laminates, and more particularly to laminated sheets of glass and sapphire.

### BACKGROUND

Corundum is a crystalline form of aluminum oxide, and is often referred to as “sapphire.” Sapphire is a hard and strong material with a hardness of 9.0 on the Mohs scale, and, as such, is highly scratch-resistant. Because of its transparency, hardness, and strength, sapphire may be an attractive alternative to materials like glass or polycarbonate for use as protective covers for displays and touchscreens of electronic devices.

### SUMMARY

An electronic device comprises a housing, a display coupled to the housing, and a protective cover coupled to the housing and covering the display. The protective cover comprises a transparent layer having a first surface facing the display and a second surface opposite the first surface. The protective cover also comprises a sapphire layer having a third surface corresponding to an exterior surface of the electronic device. The sapphire layer also has a fourth surface opposite the third surface and bonded to the second surface of the transparent layer via intermolecular forces, such as van der Waals forces. The sapphire layer may define a user input surface of the electronic device.

In some embodiments, the sapphire layer has a hardness that is greater than the transparent layer. In some embodiments, the protective cover is more flexible than a single sheet of sapphire having a thickness the same as the protective cover.

In some embodiments, the protective cover is a first protective cover, the transparent layer is a first transparent layer, and the sapphire layer is a first sapphire layer, and the electronic device further comprises a biometric sensor and a second protective cover covering the biometric sensor. The second protective cover comprises a second transparent layer and a second sapphire layer bonded to the second transparent layer by intermolecular forces, such as van der Waals forces.

A method of forming a laminated sheet comprises preparing a sapphire sheet and a base sheet, and bonding a surface of the sapphire sheet to a surface of the base sheet without adhesive.

In some embodiments, the operation of bonding the surface of the sapphire sheet to the surface of the base sheet without adhesive includes bonding the surface of the sapphire sheet to the surface of the base sheet via van der Waals forces.

In some embodiments, preparing the sapphire sheet and the base sheet comprises cleaning the surface of the sapphire sheet and cleaning the surface of the base sheet. In some embodiments, preparing the sapphire sheet and the base sheet comprises polishing the surface of the sapphire sheet to a surface roughness less than about 1000 nanometers and polishing the surface of the base sheet to a surface roughness less than about 1000 nanometers.

In some embodiments, the operation of bonding the surface of the sapphire sheet to the surface of the base sheet without adhesive includes placing the surface of the sapphire sheet in contact with the surface of the base sheet and pressing the sapphire sheet and the base sheet together.

In some embodiments, the method comprises cutting the laminated sheet into multiple protective covers for covering a display of an electronic device.

In some embodiments, the sapphire sheet is a first sapphire sheet, and the method further comprises preparing a second sapphire sheet, bonding a surface of the second sapphire sheet to the surface of the base sheet without adhesive, cutting a first protective cover comprising the first sapphire sheet and a first portion of the base sheet, and cutting a second protective cover comprising the second sapphire sheet and a second portion of the base sheet.

In some embodiments, the method further comprises includes applying a coating around an outer edge of the laminated sheet to cover a seam between the sapphire sheet and the base sheet.

A laminate configured to define an exterior surface of an electronic device comprises a glass sheet defining a first bonding surface and a first outer surface of the laminate, and a sapphire sheet defining a second bonding surface and a second outer surface of the laminate. The first bonding surface is bonded to the second bonding surface via van der Waals forces. The first bonding surface may be in direct contact with the second bonding surface.

In some embodiments, the glass sheet of the laminate comprises a recess, the first bonding surface defines a bottom surface of the recess, and the sapphire sheet is disposed in the recess.

In some embodiments, the glass sheet has a thickness less than or equal to about 400 microns and the sapphire sheet has a thickness less than or equal to about 100 microns.

In some embodiments, the laminate comprises a coating around an outer edge of the laminate to cover a seam between the sapphire sheet and the glass sheet.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows an example electronic device.

FIG. 1B shows an exploded view of a portion of the electronic device of FIG. 1A.

FIG. 2 shows a cross-sectional view of an example electronic device along section 2-2 of FIG. 1A.

FIG. 3 shows a cross-sectional view of an alternative mounting configuration along section 2-2 of FIG. 1A.

FIG. 4 shows a detail view of the example electronic device of FIG. 3.

FIG. 5 shows a cross-sectional view of another alternative mounting configuration along section 2-2 of FIG. 1A.

FIG. 6 shows an expanded cross-sectional view of the example electronic device of FIG. 5.

FIG. 7 shows a partial cross-sectional view of a protective cover for an electronic device.

FIG. 8 shows an example process for forming a protective cover for an electronic device.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Electronic devices may use protective covers over displays, touchscreens, and the like to protect the underlying components and to provide durable and functional user interface surfaces. Protective covers may be manufactured from various materials, the selection of which may depend on various factors, such as the optical properties of the material, the hardness of the material, the toughness or impact resistance of the material, and the like. For example, for many applications, glass exhibits many desirable characteristics for a protective cover. For example, glass can be highly transparent and, while it is generally a rigid material, glass still has a small degree of flexibility that makes it reasonably resistant to brittle failure (e.g., shattering or splintering) in response to impacts and bending stresses. However, glass is susceptible to scratching, and thus may degrade in both appearance and performance as it becomes more and more worn.

Sapphire, on the other hand, is very hard and scratch-resistant, and thus may improve upon glass as a material for a protective cover in at least this respect. Sapphire is, however, more brittle than glass. One consequence of its brittleness is the fact that a sheet of sapphire, such as a sheet that may be used for a protective cover of an electronic device (e.g., over a display), is liable to break or shatter if it is deformed or bent beyond a limit. Thinner sheets of sapphire are typically more flexible than thicker sheets, but sheets that are thin enough to allow for sufficient deflection during operation of a device without shattering may be too thin to actually protect the underlying display, sensor, lens, or other component.

In order to achieve the benefits of both glass and sapphire, described herein are protective covers formed by laminating a sheet of glass (or other appropriate material) with a sheet of sapphire. The sheet of sapphire may act as a scratch- and impact-resistant outer surface while the underlying glass provides a relatively more resilient and flexible base. Thus, the laminates may better protect the underlying components than a protective cover formed from either material alone.

The sapphire and glass sheets in the protective covers described herein may be bonded together via an adhesive-free bond. Such bonds may be produced by intermolecular forces between the sapphire and glass sheets. Intermolecular forces are attractive forces between neighboring molecules, and include, for example, van der Waals forces, hydrogen bonds, electrostatic forces, dipole-dipole interactions, and covalent bonds. Thus, when the sapphire and glass sheets are properly prepared and brought into contact with each other, the molecules (or atoms or ions) of the glass are attracted directly to the molecules (or atoms or ions) in the sapphire, thus bonding the sheets together without interstitial adhesives or bonding layers.

By avoiding or reducing the use of adhesives between sheets, protective covers can be produced more quickly and easily (and the overall protective covers can be thinner) because the bond can be achieved by simply bringing the sheets into direct contact with one another. Other detrimental effects of adhesives may also be avoided, such as decreased optical clarity, undesirable coloration, and increased electrical resistance. Accordingly, protective covers with layers or sheets bonded with intermolecular forces may be well suited for use in displays, lenses, biometric sensors (e.g., capacitive fingerprint sensors), and the like.

Moreover, the relative flexibility or deformability of adhesives may make them unsuitable for adhering sapphire to glass for a protective cover. For example, an adhesive that is less resistant to deformation than an overlying sapphire layer may allow the sapphire to deform in such a way that an application of pressure (e.g., from a user pressing on the protective cover with a finger or a stylus) may cause the sapphire to break. More particularly, the deformability of the adhesive layer may allow relatively large local deformations or depressions in the sapphire in response to an application of pressure. By directly bonding the sapphire to glass, this risk may be reduced or eliminated because the underlying glass layer will not allow the sapphire to deform as much in response to a local application of pressure as would an adhesive. Moreover, as noted above, an interstitial layer of adhesive may lower the optical quality of the laminate. For example, deformations caused by pressure on the sapphire layer being transferred to the adhesive layer may produce visual artifacts (such as undesirable diffraction, lensing effects, or the like).

The laminated construction of the protective covers described herein may also provide other benefits over single-sheet protective covers. In particular, the seam between the two laminate materials (e.g., the plane along which the laminates are bonded together via intermolecular forces) may help prevent the propagation of cracks or breaks between the sheets. Specifically, energy transferred to the outer, sapphire sheet as a result of an impact (e.g., from dropping a device onto uneven ground or a hard object) may cause the outer sheet to break, but once the break reaches the seam between the sheets, the energy may be transmitted along the seam instead of into the underlying sheet. Effectively, the energy may be transmitted and dissipated parallel to the surface of the underlying sheet, rather than perpendicular to the surface of the underlying sheet. While the impact may delaminate the sheets from one another, the underlying sheet may remain intact and thus continue to protect the underlying device and/or components.

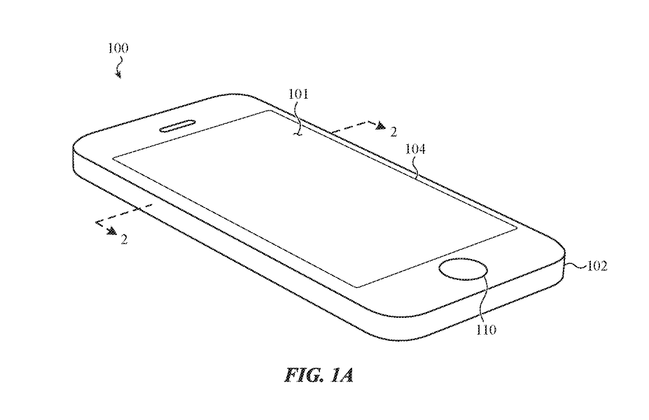

Attention is now directed to FIG. 1A, which illustrates an example of an electronic device 100. The electronic device 100 includes a housing 102, a display 104, a display cover 101, and a button cover 110.

The display 104 may include a liquid crystal display (LCD), light-emitting diode (LED) display, or any other appropriate display components, and may be positioned within and/or coupled to the housing 102. The electronic device 100 may also include touch-sensitive or force-sensitive components that provide user input functionality, such as capacitive sensing elements that facilitate detection of user inputs on an exterior surface of the device, such as the display cover 101. In such cases, the display cover 101 defines a user input surface of the electronic device 100.

The display cover 101 may be positioned above the display 104 to protect the display 104 from scratches, impact, breakage, or other physical damage. The display cover 101 may be coupled to the housing 102 of the device using an optically transmissive adhesive or other bonding technique. For example, the display cover 101 may be attached to the housing 102 using an adhesive such as a pressure sensitive adhesive film, or any appropriate bonding agent, material, or mechanism.

The button cover 110 may be disposed over a biometric sensor, such as a fingerprint sensor, that is integrated with a button of the electronic device 100. The button cover 110 may protect the underlying components of the biometric sensor from scratches, impact, breakage, or other physical damage, and may be attached to the underlying components with any appropriate adhesive, bonding agent, material, or mechanism.

The display cover 101 and the button cover 110 are laminates formed from at least a base sheet bonded to a cover sheet (e.g., a sapphire sheet) via intermolecular forces. The display cover 101 and the button cover 110 may be configured so that the sapphire sheets form exterior surfaces of the covers 101, 110. Thus, the sapphire material forms surfaces of the electronic device 100 that may be susceptible to scratching or other damage, such as touchscreen surfaces, buttons, biometric sensors, or the like.

FIG. 1B is an exploded view of the display cover 101, showing a base sheet 106 separated from a cover sheet (e.g., the sapphire sheet 108). When the display cover 101 is assembled and coupled to the housing (e.g., the housing 102, FIG. 1A), one surface of the base sheet 106 faces the display (e.g., the display 104, FIG. 1A), and another surface of the base sheet 106 is bonded, without adhesive, to a surface of the sapphire sheet 108. The opposite surface of the sapphire sheet 108 forms an exterior surface of the electronic device 100. The sapphire sheet 108 may have a higher hardness than the underlying base sheet 106, and thus may provide a hard, scratch-resistant exterior surface of the electronic device 100.

The base sheet 106 may be a transparent layer that is formed from or includes any appropriate material, such as soda-lime glass, chemically strengthened glass, borosilicate glass, aluminosilicate glass, fused silica glass, fused quartz, or the like. Other materials are also possible, including polymers, crystalline materials (e.g., sapphire, zirconia), or the like. As noted above, the cover sheet that is bonded to the base sheet 106 is a sapphire sheet 108. However, in some cases, the cover sheet includes or is formed from other materials, such as glass, polymer, ceramic (e.g., aluminum oxynitride, spinel), or diamond. The foregoing materials are merely examples, and the base sheet 106 and the cover sheet (e.g., the sapphire sheet 108 in the described example) may be formed from or include any materials that form intermolecular bonds when the materials are placed in contact with one another. For example, materials that are dipolar or have dipolar molecules (e.g., molecules having a portion that exhibits a positive charge and another portion that exhibits a negative charge) may form dipole-dipole interactions with each other (a type of intermolecular force) when the materials are placed in contact with each other. In particular, negatively charged portions of the molecules of one material are attracted to positively charged portions of the molecules of the other material. The combined effect of these molecular attraction bonds the two materials together without adhesive. Accordingly, the base sheet 106 and the sapphire sheet 108 may be formed from or include any materials that include dipolar molecules and that bond to one another via dipole-dipole interactions.

Because the sapphire sheet 108 is laminated to the base sheet 106, the sapphire sheet 108 may be made thin enough so that it can flex sufficiently without shattering or breaking (e.g., about 20-200 microns thick, though other dimensions may be used). That is, whereas a thicker sheet of sapphire may break if subjected to even small deformations, a thinner sheet of sapphire may withstand more bending than a thicker sheet. Further, while a thin sapphire sheet (e.g., less than about 200 microns thick) alone may not be tough enough to withstand normal use in an electronic device, the base sheet 106 to which the sapphire sheet 108 is laminated, which may be about 100-1000 microns thick, provides a resilient and flexible base for the sapphire sheet, thus compensating for the relative delicateness of the sapphire material. The resulting display cover 101 may be more flexible than a single sheet of sapphire having the same thickness as the laminated display cover 101.

Portions of one or both of the base sheet 106 and the sapphire sheet 108 may be painted or coated prior to being attached to the electronic device 100. The painted or coated portions may be located on the display cover 101 so as to cover internal or non-cosmetic portions of the electronic device, such as areas where adhesive is applied to bond the display cover 101 to the electronic device 100, areas where internal components of the electronic device 100 would otherwise be visible, or the like. A paint or coating may be applied after the display cover 101 is assembled, but before the display cover 101 is attached to the electronic device 100. On the other hand, a paint or coating may be applied prior to lamination of the base sheet 106 to the sapphire sheet 108.

FIG. 1B also shows an exploded view of the button cover 110, showing a base sheet 112 separated from a sapphire sheet 114. In a device that includes both a button cover 110 and a display cover 101, the button cover 110 may have substantially the same construction (e.g., materials and thicknesses) as the display cover 101. In some cases, however, they may have different constructions. For example, the sapphire sheet 108 of the display cover 101 may have a first thickness, and the sapphire sheet 114 of the button cover 110 may have a second thickness different from the first thickness (either thicker or thinner). As another example, the combined thickness of the base sheet 106 and the sapphire sheet 108 may be different than the combined thickness of the base sheet 112 and the sapphire sheet 114.

Where the button cover 110 covers a biometric sensor, the materials and dimensions of the button cover 110 may be selected to be suitable for that particular application. For example, in the case of a capacitive biometric sensor, a material with a low dielectric constant or anisotropic properties may be selected for the base sheet 112 of the button cover 110. Also, the thickness of the base sheet 112 and the sapphire sheet 114 may be selected to allow sufficient capacitive coupling between a user's finger or other body part and an underlying capacitive sensor (e.g., each sheet may have a thickness between about 50 and 100 microns).

The surfaces of the sapphire sheets 108, 114 may be aligned with the same or different planes of the crystalline structure of the sapphire (e.g., c-plane, r-plane, m-plane, n-plane, or a-plane). The particular alignment of the sapphire crystals relative to the surfaces of the sapphire sheets 108, 114 may be selected based on the desired properties or parameters of the sapphire sheets 108, 114. For example, the exterior surface of the sapphire sheet 108, which covers the display 104, may be parallel to a plane of the sapphire crystal that provides a high strength or resistance to breakage during bending (e.g., the a-plane or m-plane). This property may be useful for the sapphire sheet 108, as the display cover 101 may be subject to more bending and deformation during normal use than smaller covers, such as the button cover 110. As another example, the exterior surface of the sapphire sheet 114, which may cover a biometric sensor, may be parallel to a plane that provides a higher dielectric constant (e.g., the c-plane) relative to other planes. In this case, because the button cover 110 is small and less likely to be deformed during normal use, and because the biometric sensor may be sensitive to the dielectric properties of the button cover 110, the strength of the sapphire sheet 114 may be less important than its dielectric properties.

As shown in FIGS. 1A-1B, the electronic device 100 is a smartphone, but this is merely one example, and other devices are also possible. Indeed, the present discussion may apply equally to tablet computers, laptop computers, gaming devices, watches, biometric monitors, and the like. For example, a protective cover of a watch (e.g., a smartwatch) may comprise a sapphire sheet laminated and bonded to a base sheet via intermolecular forces. As another example, a display or a touchpad of a laptop computer may include a protective cover with a sapphire sheet bonded to a base sheet via intermolecular forces, as described herein. Other devices and applications are also contemplated.

In the present description, aspects of laminated protective covers are described with respect to the display cover 101. It will be understood that the discussion applies equally to the configuration and the method of producing the button cover 110, as well as any other types of protective covers, such as protective covers for watches (also referred to as watch crystals), lenses, and the like. Moreover, while the display cover 101 and the button cover 110 are shown in the figures as having only two layers, this is merely an example, and the covers 101, 110 may have more layers, such as additional layers of sapphire, glass, polymers, or other materials not mentioned. For example, a protective cover may include two layers of sapphire and a layer of another material, such as glass, positioned between the sapphire layers. In such a case, both of the exterior surfaces of the protective layer benefit from the hardness and scratch resistance of the sapphire material, while the protective cover still benefits from the additional toughness and resilience imparted by the less brittle middle layer.

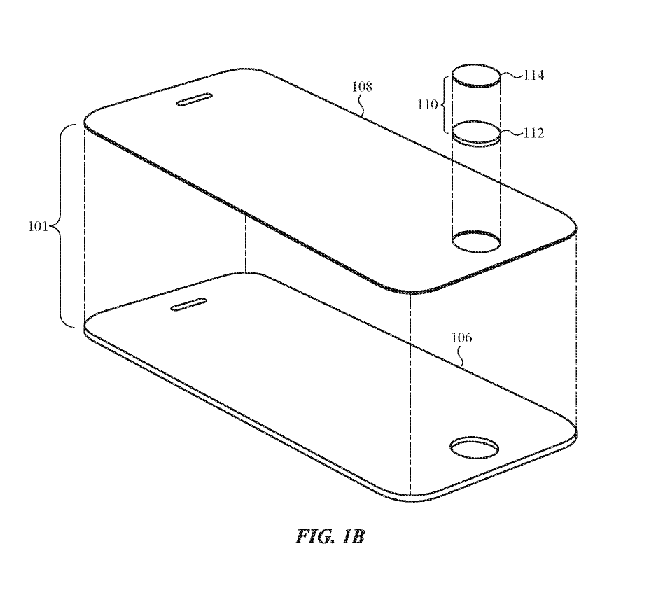

In the electronic device 100 of FIG. 1A, the display cover 101 may be coupled to the housing 102 in various ways and with various structures. For example, the display cover 101 may extend to (e.g., be flush with) the outer edges of the housing 102. FIG. 2 is a cross-sectional view of the electronic device 100 through section 2-2 in FIG. 1A, showing an embodiment where the display cover 101 extends to an outer edge of the housing 102. (For simplicity, the internal volume of the housing 102 is shown in the cross-sectional views as being empty. It will be understood that this space may instead be occupied by electronic device components, including but not limited to display components, batteries, circuit boards, processors, and the like.) In some cases, the edges of the display cover 101 are rounded or otherwise contoured to present a smooth and attractive corner or edge of the device.

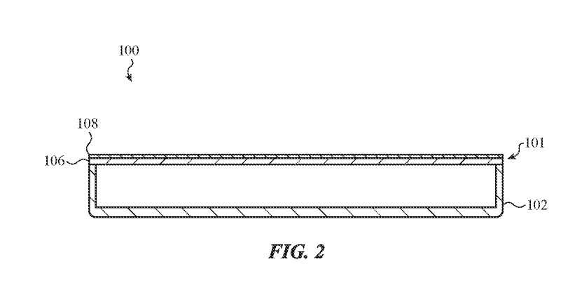

FIG. 3 is a cross-sectional view of the electronic device 100 through section 2-2 in FIG. 1A, showing an embodiment where the edges of the display cover 101 are surrounded by a portion of the housing 102. Specifically, the housing 102 includes a bezel 204 that extends away from a main portion of the housing, and surrounds the edge of the display cover 101 such that the seam between the base sheet 106 and the sapphire sheet 108 is not exposed to the environment. This may help prevent the display cover 101 from delaminating during normal use and operation of the device, or due to impacts, application of shear forces to the protective cover, or the like. Moreover, because the edge is not exposed, the edge may not need to be finished, rounded, or otherwise contoured. Further, if the sheets are not perfectly aligned (e.g., one sheet is shifted with respect to another), any resulting edge discontinuities may be hidden from view and from contact with a user's fingers or other objects. Thus, manufacturing tolerances may be more relaxed for embodiments where the display cover 101 is surrounded by the bezel 204 or a portion of the housing 102.

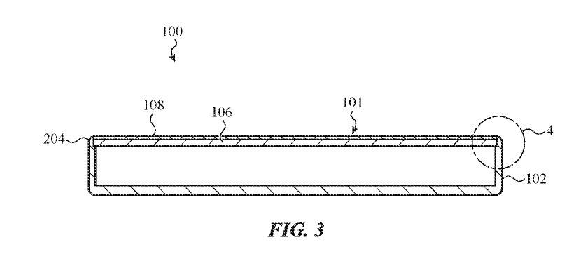

FIG. 4 is a detail view of the electronic device 100, showing the area designated as 4 in FIG. 3. FIG. 4 further illustrates the bezel 204 surrounding the edge of the display cover 101 such that the seam between the base sheet 106 and the sapphire sheet 108 is not exposed. For example, a portion of an interior-facing surface of the display cover 101 may be supported by a support 206 of the housing 102. In some cases, the interior-facing surface of the display cover 101 may be glued, bonded, or otherwise affixed to the support 206, thereby retaining the display cover 101 to the housing 102.

Instead of a portion of the housing 102 surrounding the outer edge of the display cover 101, the outer edge may be covered by a gasket, paint, coating, adhesive, glue, epoxy, or other material or structure that effectively seals the outer edge of the display cover 101. In such cases, the additional surrounding material may help prevent delamination of the display cover 101 as well as improving the tactile properties of the protective cover (e.g., by covering sharp or highly angular edges and corners).

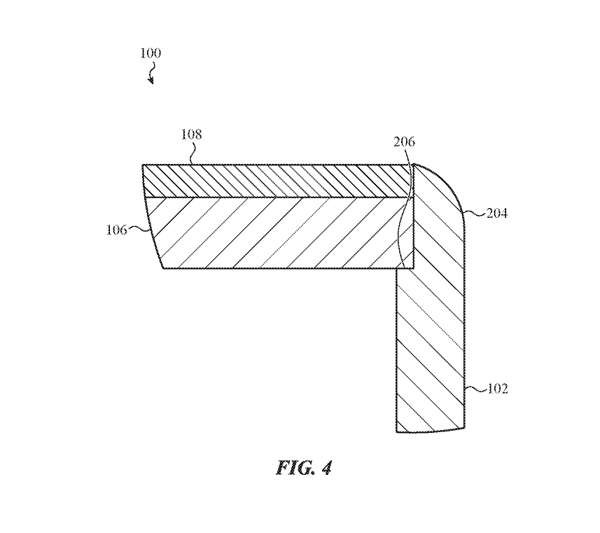

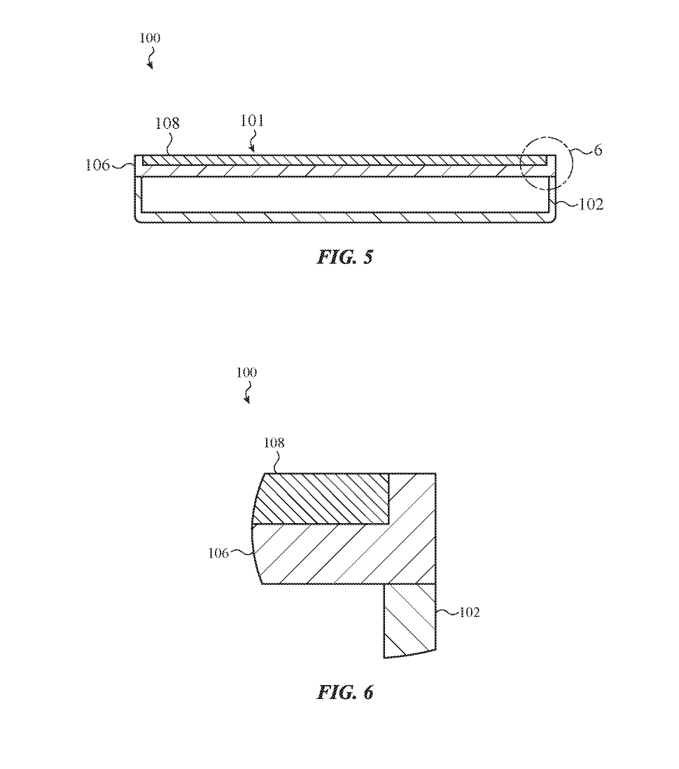

FIG. 5 is a cross-sectional view of the electronic device 100 through section 2-2 in FIG. 1A, showing an embodiment where the sapphire sheet 108 is set into a recess in the base sheet 106. In particular, a recess defined by a bottom surface and one or more walls surrounding at least a portion of the bottom surface may be machined, cut, laser-etched/ablated, or otherwise formed into the base sheet 106. The sapphire sheet 108 may be formed or cut such that it fits within the recess. The depth of the recess in the base sheet 106 may be substantially equal to the thickness of the sapphire sheet 108, such that the portions of the base sheet 106 that surround the sapphire sheet 108 when the protective cover is assembled are substantially flush with the exterior surface of the sapphire sheet 108. FIG. 6 is an expanded cross-sectional view of the electronic device 100, showing the area 6 in FIG. 5. FIG. 6 further illustrates the sapphire sheet 108 placed within a recess in the base sheet 106. While the housing shown in FIGS. 5-6 do not include a bezel as shown in FIGS. 3-4, the protective cover shown in FIGS. 5-6 could also be used in an embodiment with a bezel.

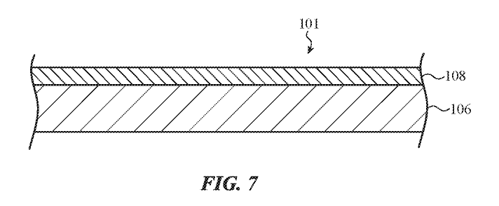

FIG. 7 is a partial cross-sectional view of the display cover 101 through section 2-2 in FIG. 1A. While FIG. 7 depicts the display cover 101, it will be understood that the present discussion applies to other protective covers, such as the button cover 110 of the electronic device 100, a lens cover (not shown) over a camera lens (not shown) of the electronic device 100, or the like.

The base sheet 106 may be any appropriate thickness. For example, the base sheet 106 may be less than or equal to about 200 microns, or less than or equal to about 400 microns. Other thicknesses, such as thicknesses up to about 1000 microns, are also contemplated. As discussed below, the base sheet 106 may be thicker than the sapphire sheet 108.

The display cover 101 also includes a sapphire sheet 108. The sapphire sheet may be any appropriate thickness, such as less than or equal to about 20 microns, less than or equal to about 100 microns, or less than or equal to about 200 microns. The thickness of the sapphire sheet 108 may be selected such that the sapphire sheet 108 is sufficiently strong and flexible for use in a protective cover for an electronic device. For example, a sapphire sheet about 50 microns thick may provide a suitable balance between strength, flexibility, and manufacturability.

As noted above, the base sheet 106 and the sapphire sheet 108 are bonded to one another via intermolecular forces. That is, the molecules of the sapphire sheet 108 interact with the molecules of the base sheet 106 such that the sheets are attracted to one another. For example, the molecules of both the base sheet 106 and the sapphire sheet 108 may be dipolar, such that when they are brought into sufficient proximity with one another the molecules are attracted one another with sufficient force to generate a laminate that is strong enough for use as a protective cover of an electronic device.

Various types of intermolecular forces, alone or in concert with one another, may bond the base sheet 106 and the sapphire sheet 108, including van der Waals forces, hydrogen bonds, electrostatic forces, dipole-dipole interactions, covalent bonds, and the like. In the case of hydrogen bonds, the sapphire and glass may contain surface water, or water that is chemically and/or physically bonded to the sheets, giving rise to an adhesion between the sapphire and the glass. The particular type of intermolecular force or forces that bond the base sheet 106 and the sapphire sheet 108 may depend on the material or composition (e.g., microstructure structure or phase) of the base sheet 106 and the sapphire sheet 108, the surface treatments or finish of the sheets 106, 108, the presence of additional materials such as dopants or alloying elements in the sheets 106, 108, and the like. In some cases, such as when the base sheet 106 is glass, the primary intermolecular forces bonding the sheets together may be van der Waals forces.

In some cases, the base sheet 106 and the sapphire sheet 108 may be bonded to one another using diffusion bonding. For example, the base sheet 106 and the sapphire sheet 108 may be placed in contact with one another and optionally pressed together in order to cause molecules or atoms of the sheets to intermingle at the joint between the contacting surfaces. In this way, the gap between the sheets 106, 108 may effectively disappear, and the two sheets 106, 108 become one solid component.

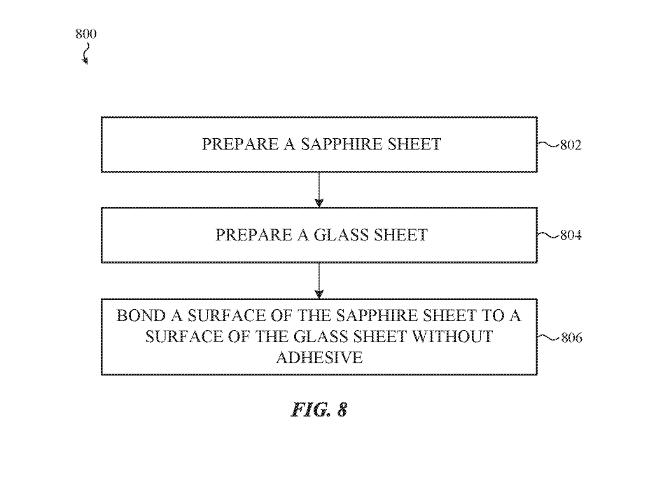

FIG. 8 is a flow chart of a method 800 for forming a protective cover. The method 800 may be used to produce the display cover 101 and the button cover 110 of FIGS. 1A-1B. The method 800 may also be used to form a laminate for any use or purpose, such as a cover for a mirror, a watch crystal, a window, a camera lens (or other optical component or device), or the like.

At operation 802, a sapphire sheet is prepared for assembly into a protective cover. The sapphire sheet may take the form of a substantially planar sheet of sapphire material (Al2O3) about 100 microns in thickness. Other dimensions are also contemplated, such as about 20 or 50 microns thick.

Preparing the sapphire sheet may include forming the sapphire sheet, for example, by separating a sapphire sheet from a larger piece of sapphire (e.g., using laser cutting techniques). Preparing the sapphire sheet may further include polishing one or both surfaces of the sapphire sheet to a desired surface polish. The opposite surfaces of the sapphire sheet may be polished to different degrees (e.g., such that one surface is rougher than the other), or they may be polished to substantially the same degree. In some cases, the sapphire sheet need not be treated or polished after being produced. Rather, it may be suitable for forming into a protective cover as-is.

Preparing the sapphire sheet may also include cleaning at least the surface of the sapphire sheet that will contact the glass sheet to remove dust, oils, water, or any other particulate or liquid or other contaminants. This may be achieved by cleaning the surface with a solvent or other cleaning solution.

At operation 804, a glass sheet is prepared for assembly into a protective cover. The glass sheet may take the form of a substantially planar sheet of glass (or other appropriate material, as described above) about 400 microns thick, though other thicknesses are also possible. Preparing the glass sheet may include the same or similar processes used to prepare the sapphire sheet, including, for example, separating or cutting the glass sheet from a larger glass sheet, cleaning the glass sheet, polishing one or more surfaces of the sheet, and the like.

After preparation, the surfaces of the glass and sapphire sheets that are to be bonded together may have surface roughness parameters of between about 100 to 1000 nanometers. The surface roughness parameter may be any appropriate measure of surface roughness, such as an arithmetic average of absolute values of the surface features (e.g., peaks and troughs) of the sapphire sheet. In some cases, the operations of preparing the sapphire and/or glass sheets (operations 802, 804) include polishing the sheets to achieve a desired surface roughness, such as less than about 1000 nanometers.

The glass sheet may share approximately the same outer shape and dimensions as the sapphire sheet. Accordingly, when the sapphire sheet is laminated to the glass sheet to create the protective cover (operation 806, below), the edges along the outer perimeters of the sheets will be substantially flush with one another (as shown in FIGS. 2-4). The glass and sapphire sheets need not have the same shape and/or dimensions, however. For example, the glass sheet may be a rectangular sheet, and the sapphire sheet may be a rectangular sheet that is smaller than the glass sheet such that the sapphire sheet only covers a portion of the area of the glass sheet. This may be used, for example, where a display or touchscreen will only occupy a portion of the area of the protective cover, and thus the extra protection of the sapphire sheet is only required in that area.

At operation 806, a surface of the sapphire sheet is bonded to a surface of the glass sheet without adhesive. For example, a surface of the sapphire sheet may be placed in contact with a surface of the glass sheet. The sapphire and glass sheets may be placed in contact manually, by a human, or they may be placed in contact by a machine (either automatically controlled or controlled by a human).

As a result of being placed in contact with one another, the surfaces of the sapphire and glass sheets that are in contact with one another bond to one another via intermolecular forces, such as van der Waals forces, hydrogen bonds, electrostatic forces, dipole-dipole interactions, covalent bonds, and the like. Diffusion bonding may also occur to completely or partially bond the sheets.

A force may be applied to one or both of the sapphire and glass sheets to press the sheets together. This force may aid in the forming of (and/or increase the strength of) the bond between the sheets. The force may be applied by placing the sheets in a vacuum bag, and then drawing air out of the vacuum bag. Alternatively or additionally, the force may be applied by placing the sheets between two platens that are configured to apply a compressive force to the glass-sapphire laminate.

After the sapphire sheet and the base sheet are bonded to one another without adhesive, a coating, paint, adhesive, seal, or other material may be applied around at least a portion of an outer edge of the laminated sheet to cover a seam between the sapphire and glass sheets, as described above.

Any of the operations of the method 800 may occur at an elevated temperature. For example, the operation of placing the sapphire sheet against the glass sheet (operation 806) may occur at an elevated temperature, such as above about 20° C., above about 50° C., above about 100° C., or any other appropriate temperature. Moreover, the optional operation of applying a force to press the two sheets together may occur at the elevated temperature. In some cases, all or part of the method 800 may occur inside a heating chamber, such as an oven. The elevated temperature may refer to the temperature of an environment surrounding the sheets, or a temperature to which the sheets themselves are heated. Performing operations of the method 800 at an elevated temperature may allow shorter processing times, greater bond strength, or may facilitate the formation of different types of bonds or a different combination of bonding forces. For example, heating the sheets may result in a relatively greater amount of diffusion bonding as compared to van der Waals force bonding than would occur if the sheets were not heated.

All or part of the method 800 may be performed after the sapphire and glass sheets are cut or formed into their final shapes. For example, where the laminates are to be used as a protective cover for an electronic device, the glass and sapphire sheets may each be cut into the final shapes and individually prepared (including, for example, lapping and polishing of the sheets), and then bonded together to form the final component. On the other hand, all or part of the method 800 may be performed before the sapphire and glass sheets are cut or formed into their final shapes. For example, sheets of sapphire and glass that are large enough to be cut into multiple parts may be prepared for bonding and bonded together (as described with respect to operation 806). Subsequent to bonding, the sheets may be cut or otherwise formed into their final shapes, for example, by laser cutting individual laminates from the larger sheets. The latter process may be used for smaller components, such as watch crystals and button covers, as it may be difficult to manufacture such components individually.

In some cases, multiple laminates may be formed by placing multiple sheets of either glass or sapphire on a larger sheet of the other material. For example, in some cases, a large glass sheet is prepared for bonding, as are multiple sapphire sheets that are already cut or formed into a final shape (operations 802, 804). The multiple sapphire sheets are then placed on the glass sheet and bonded to the glass sheet (operation 806), and individual laminates are formed by cutting along the edges of the sapphire sheets. (Of course, the glass and sapphire materials may be swapped in the foregoing examples, such that multiple, smaller glass sheets are bonded to a single larger sapphire sheet.)

Where bonding takes place before the final cutting of the laminates from a larger laminated sheet, certain processes or operations may take place either before or after the bonding operation. For example, the outer surfaces of the laminate (e.g., the surface that is used as the exterior surface of a device and the surface that is used to contact or face the device) may be polished after the sheets are bonded together (operation 806) but before the sheets are cut into the final shapes. In particular, it may be easier or more efficient to polish larger laminated sheets than the smaller, end-use sized laminates. Moreover, the larger sheets may be stronger and thus more able to withstand the forces and pressures applied during such processing steps.

Some or all of the operations described with respect to the method 800 may occur in a clean-room environment. For example, the method 800 may be performed in an international standards organization (ISO) clean room environment (e.g., ISO class 1-9). Performing the method 800 (or a subset of the operations of the method 800) in a clean-room environment helps to prevent dust and other particles from being captured between the sheets, which may prevent the sheets from bonding to one another in the area surrounding the dust particle. For example, a single dust particle may result in an un-bonded area between the glass and sapphire sheets of up to one centimeter.

While any methods disclosed herein have been described and shown with reference to particular operations performed in a particular order, it will be understood that these operations may be combined, sub-divided, or re-ordered to form equivalent methods without departing from the teachings of the present disclosure. Accordingly, unless specifically indicated herein, the order and grouping of the operations is not a limitation of the present disclosure.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device, comprising:
a housing;
a display coupled to the housing; and
a protective cover coupled to the housing and covering the display, the protective cover comprising:
a transparent layer having a first surface facing the display and a second surface opposite the first surface; and
a sapphire layer having a third surface corresponding to an exterior surface of the electronic device, and having a fourth surface opposite the third surface and bonded to the second surface of the transparent layer via intermolecular forces.

2. The electronic device of claim 1, wherein the sapphire layer has a hardness that is greater than the transparent layer.

3. The electronic device of claim 1, wherein the protective cover is more flexible than a single sheet of sapphire having a thickness the same as the protective cover.

4. The electronic device of claim 1, wherein the transparent layer is bonded to the sapphire layer by van der Waals forces.

5. The electronic device of claim 1, wherein the sapphire layer defines a user input surface of the electronic device.

6. The electronic device of claim 1, wherein:
the protective cover is a first protective cover;
the transparent layer is a first transparent layer;
the sapphire layer is a first sapphire layer; and
the electronic device further comprises:
a biometric sensor; and
a second protective cover covering the biometric sensor and comprising:
a second transparent layer; and
a second sapphire layer bonded to the second transparent layer by intermolecular forces.

7. A method of forming a laminated sheet, comprising:
preparing a sapphire sheet and a base sheet; and
bonding a surface of the sapphire sheet to a surface of the base sheet without using an adhesive.

8. The method of claim 7, wherein bonding the surface of the sapphire sheet to the surface of the base sheet includes bonding using van der Waals forces.

9. The method of claim 7, further comprising applying a coating around an outer edge of the laminated sheet to cover a seam between the sapphire sheet and the base sheet.

10. The method of claim 7, wherein preparing the sapphire sheet and the base sheet comprises:
cleaning the surface of the sapphire sheet; and
cleaning the surface of the base sheet.

11. The method of claim 7, wherein preparing the sapphire sheet and the base sheet comprises:
polishing the surface of the sapphire sheet to a surface roughness less than about 1000 nanometers; and
polishing the surface of the base sheet to a surface roughness less than about 1000 nanometers.

12. The method of claim 7, wherein bonding the surface of the sapphire sheet to the surface of the base sheet comprises:
placing the surface of the sapphire sheet in contact with the surface of the base sheet; and
pressing the sapphire sheet and the base sheet together.

13. The method of claim 7, further comprising cutting the laminated sheet into multiple protective covers for covering a display of an electronic device.

14. The method of claim 7, wherein:
the sapphire sheet is a first sapphire sheet; and
the method further comprises:
preparing a second sapphire sheet;
bonding a surface of the second sapphire sheet to a surface of the base sheet without adhesive;
cutting a first protective cover comprising the first sapphire sheet and a first portion of the base sheet; and
cutting a second protective cover comprising the second sapphire sheet and a second portion of the base sheet.

15. A laminate configured to define an exterior surface of an electronic device, comprising:
a glass sheet defining a first bonding surface and a first outer surface of the laminate; and
a sapphire sheet defining a second bonding surface and a second outer surface of the laminate;
wherein the first bonding surface is bonded to the second bonding surface via van der Waals forces.

16. The laminate of claim 15, wherein the first bonding surface is in direct contact with the second bonding surface.

17. The laminate of claim 15, wherein:
the glass sheet comprises a recess;
the first bonding surface defines a bottom surface of the recess; and
the sapphire sheet is disposed in the recess.

18. The laminate of claim 15, wherein:
the glass sheet has a thickness less than or equal to about 400 microns; and
the sapphire sheet has a thickness less than or equal to about 100 microns.

19. The laminate of claim 15, further comprising a coating around an outer edge of the laminate to cover a seam between the sapphire sheet and the glass sheet.

20. The laminate of claim 15, wherein the glass sheet and the sapphire sheet both include dipolar molecules.
